(19) United States
(12) Patent Application Publication
(10) Pub. No.: US 2005/0189089 A1
(43) Pub. Date: Sep. 1, 2005

(54) Fluidic apparatus and method for cooling a non-uniformly heated power device

(75) Inventor: Andrew Miner, Austin, TX (US)

Correspondence Address: ZAGORIN O'BRIEN GRAHAM LLP, 7600B N. CAPITAL OF TEXAS HWY., SUITE 350, AUSTIN, TX, 78731, US

(73) Assignee: NANOCOOLERS INC., AUSTIN, TX (US)

(21) Appl. No.: 10/789,205

(22) Filed: Feb. 27, 2004

(51) Int. Cl. H05K 7/20

(52) U.S. Cl. 165/80.4; 361/699

(57) ABSTRACT

A fluidic apparatus and method for cooling a non-uniformly heated heat source such as an integrated circuit. The apparatus preferentially cools a non-uniformly heated integrated circuit. A coolant is introduced into a high-power region of the integrated circuit through an inlet. The coolant absorbs heat from this region and cools it. Thereafter, the coolant is transferred to the low-power region of the integrated circuit. After the coolant absorbs heat from the low-power region, it is removed from an outlet, which is connected to the low-power region of the integrated circuit.

### BACKGROUND

The present invention relates to the field of cooling systems. More specifically, the disclosed invention provides a fluidic method and apparatus for cooling a non-uniformly heated integrated circuit using moving fluids.

In most power devices, it has been observed that the dissipation of power across the power device is not uniform. An example of one such device is an integrated circuit. The non-uniform power dissipation can be attributed to the presence of multiple components in the power device. These components have different loads that cause the power dissipated in each of the components to be different. If non-uniformly heated regions are cooled in a uniform manner, then different components of the power device will have different resulting temperatures.

There are various systems available that are used to cool power devices (specifically integrated circuits), some of which are described hereinafter.

Japanese Patent No. 7321265, published on Dec. 8, 1995 and entitled “Cooling Structure in Integrated Circuit Element Module”, describes a cooling structure for cooling the integrated circuit elements. The system has a heat sink connected to the integrated circuit elements. In addition, the cooling structure includes a main duct, which is connected to the heat sink. Further, a coolant-carrying device is connected to the main duct to carry a coolant in the main duct.

Japanese Patent No. 6188582, published on Jul. 8, 1994 and entitled “Cooling and Feeding Mechanism of Integrated Circuit”, describes another cooling system for an integrated circuit. A liquid coolant is introduced through a liquid coolant inlet and is sprayed from a nozzle against the base of a cooling part provided above the integrated circuit.

However, as these systems remove heat relatively uniformly from the integrated circuit, they are unable to address the need for increased cooling at regions that require higher heat dissipation. Therefore, the resulting temperature distribution in the integrated circuit (having non-uniform power dissipation) still remains relatively non-uniform.

In the light of the above discussion, there is a need for a fluidic apparatus and method that can remove heat from a power device in a non-uniform manner. This will minimize the formation of “hot spots” on the power device, thereby increasing the reliability and improving the performance of the power device.

### SUMMARY

It is an object of the disclosed invention to provide a fluidic apparatus and method for cooling a heat source.

It is a further object of the disclosed invention to provide a fluidic apparatus and method for cooling a non-uniformly heated heat source.

An integrated circuit may dissipate power non-uniformly, causing a non-uniform temperature distribution across the integrated circuit. The disclosed method preferentially cools the non-uniformly heated integrated circuit so that a more uniform temperature distribution is created across the integrated circuit after cooling. This method involves introducing a coolant in the high-power region of the integrated circuit. The coolant absorbs heat from this region and cools it. Thereafter, the coolant is transferred to the low-power region of the integrated circuit. After the coolant absorbs heat from the low-power region, it is removed from the integrated circuit.

The apparatus for the disclosed invention comprises an inlet for a coolant, means for transferring the coolant from the high-power region to the low-power region of the integrated circuit, and an outlet for removing the coolant from the integrated circuit. The inlet is connected to the high-power region of the integrated circuit and the outlet is connected to the low-power region of the integrated circuit.

### BRIEF DESCRIPTION OF THE DRAWINGS

Various embodiments of the invention will hereinafter be described in conjunction with the appended drawings provided to illustrate and not to limit the invention, wherein like designations denote like elements, and in which:

FIG. 1 is a block diagram of an integrated circuit with a high and a low temperature region;

FIG. 2 is a flowchart that illustrates the method for cooling a non-uniformly heated integrated circuit in accordance with an embodiment of the invention;

FIG. 3 is a block diagram of a cooling structure in which the coolant is introduced parallel to the plane of the integrated circuit;

FIG. 4A and FIG. 4B are top and bottom isometric views of a cooling structure in which the coolant is introduced perpendicular to the plane of the integrated circuit;

FIG. 5 is a block diagram of an integrated circuit with high, moderate and low power regions;

FIG. 6 is a flowchart illustrating the method of cooling an integrated circuit with high, moderate and low power regions of the integrated circuit, in accordance with another embodiment of the disclosed invention; and

FIG. 7 is a block diagram of an exemplary cooling structure that can be used to cool an integrated circuit with high, moderate and low power regions.

### DETAILED DESCRIPTION

The disclosed invention provides a fluidic apparatus and method for cooling a non-uniformly heated power device. An example of such a power device is an integrated circuit with non-uniform power dissipation.

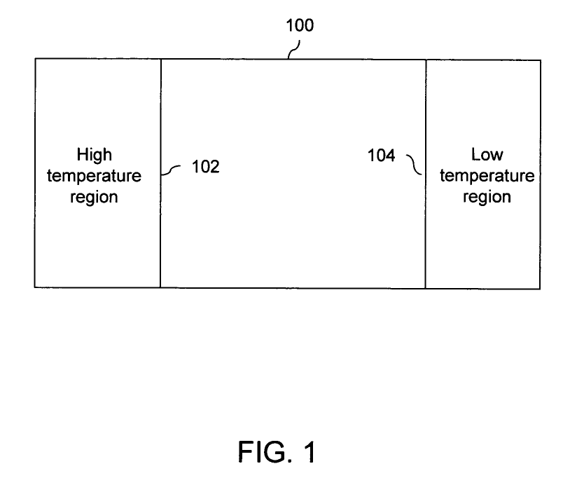

FIG. 1 is a block diagram of an integrated circuit 100, which has multiple components with different amounts of power dissipation. Since the power dissipates in the form of heat, if this integrated circuit were cooled uniformly, a non-uniform temperature distribution would develop across its surface. Integrated circuit 100 has a high temperature region 102 and a low temperature region 104.

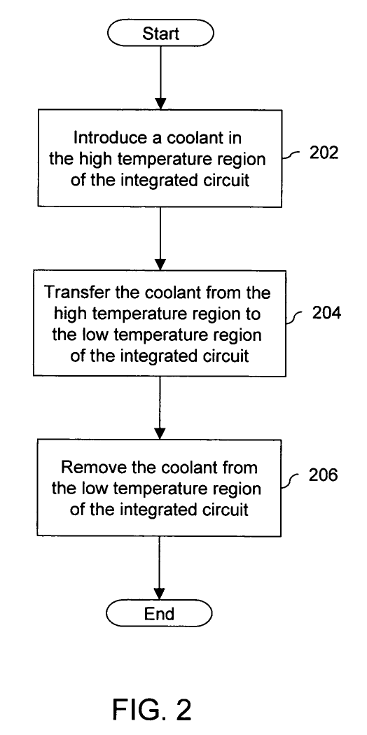

FIG. 2 is a flowchart that illustrates the method for cooling a non-uniformly heated integrated circuit in accordance with an embodiment of the invention. This method involves preferential cooling of the integrated circuit so that a more uniform temperature distribution is created across it after the cooling. The flowchart shows a single cooling cycle that is repeated multiple times in the process of cooling the integrated circuit. At step 202, a coolant is introduced in the high-power region of the integrated circuit. The coolant may be used either as a single-phase coolant or as a two-phase coolant. In a single-phase cooling scheme, a cold coolant passes over the heated power device, absorbs heat from it, and is then piped away from the power device. In a two-phase cooling scheme, a two-phase liquid-gas coolant passes over the heated power device. The liquid in the two-phase coolant vaporizes and the heat is carried away from the power device. The vapors are then piped away from the power device. Examples of coolants that can be used to cool the integrated circuit may include water, fluoroinert, and liquid metals like sodium potassium eutectic alloy, gallium-indium alloy, mercury, bismuth, etc. It should be apparent to one skilled in the art that the list of coolants mentioned herein is not exhaustive and various other coolants may also be used to cool the integrated circuit.

As the coolant is introduced in the high-power region of the integrated circuit, it absorbs heat from this region. Thereafter, at step 204 the coolant is transferred to the low-power region of the integrated circuit. After the coolant absorbs heat from the low-power region, it is removed from the integrated circuit at step 206.

The method described above removes heat non-uniformly from the integrated circuit, thereby creating a more uniform temperature distribution across the integrated circuit. A higher amount of heat is removed from the high-power region and a lower amount of heat is removed from the low-power region. This is because the heat removed from a hot device is directly proportional to the temperature difference between the hot device and the coolant. Therefore, when the coolant is introduced in the high-power region of the integrated circuit first, a high temperature difference leads to high heat removal from the region. The temperature of the coolant rises as it absorbs heat from the high-power region. As a result, the coolant that moves in the low-power region has an increased temperature. Therefore, the temperature difference between the low-power region and the coolant is lower (as compared to the temperature difference between the high-power region and the coolant), thereby leading to less heat removal from the low-power region of the integrated circuit. The preferential cooling of the integrated circuit in this manner leads to a more uniform temperature distribution over the integrated circuit.

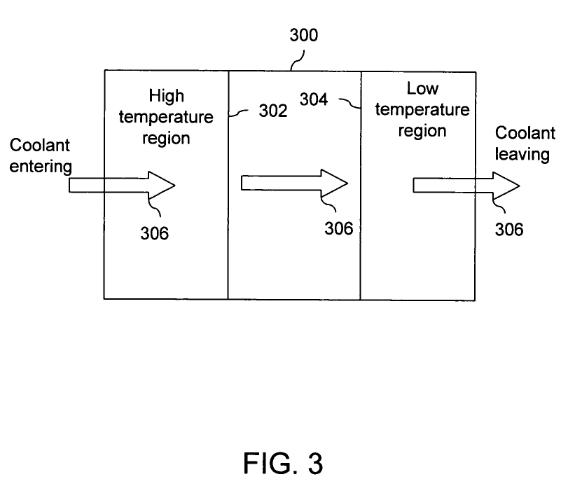

The coolant (mentioned above) may be introduced in the integrated circuit in various ways. In accordance with an embodiment of the disclosed invention, the coolant is introduced parallel to the plane of the integrated circuit. FIG. 3 is a block diagram of the integrated circuit in which the coolant is introduced parallel to the plane of the integrated circuit. As shown in the figure, an integrated circuit 300 has a high-power region 302 on its left side and a low-power region 304 on its right side. The left side of the integrated circuit may comprise high-power density microprocessor components such as a floating-point unit, while its right side may comprise low-power density components such as cache memory. This may result in left-right bias in power dissipation as shown in the figure. In order to preferentially cool the integrated circuit, the coolant is introduced from the left side and is removed from the right side. The coolant is introduced parallel to the plane of integrated circuit 300, as shown by arrows 306.

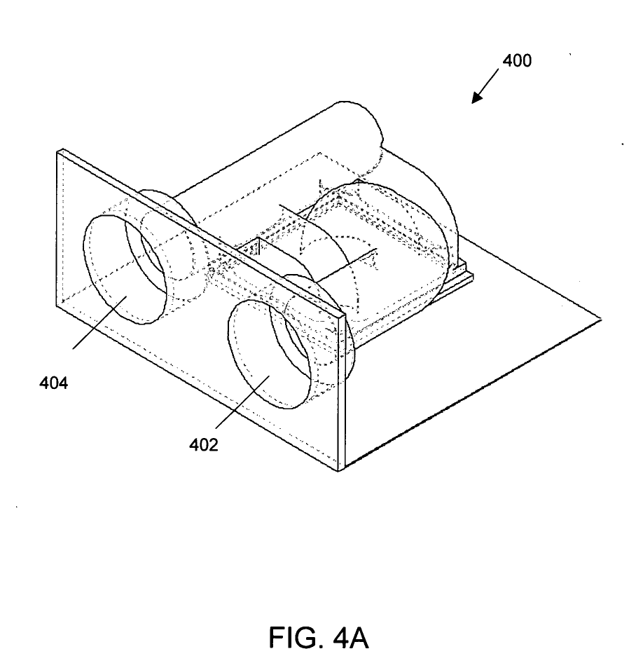

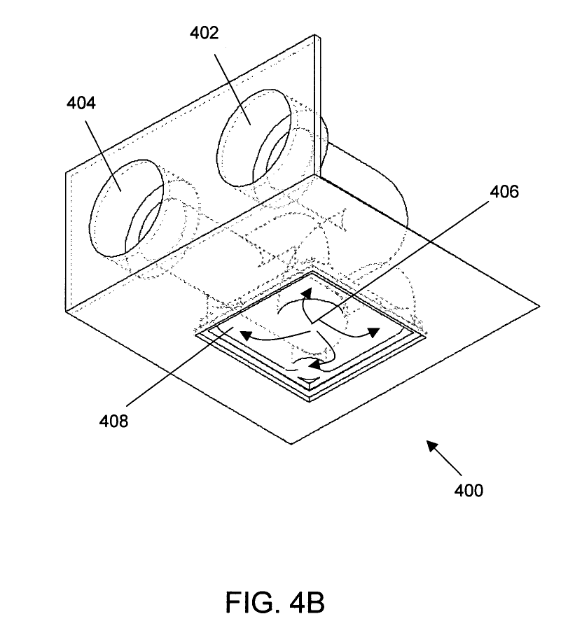

The coolant may also be introduced perpendicular to the plane of the integrated circuit. FIG. 4A and FIG. 4B are top and bottom isometric views of a cooling structure in which the coolant is introduced perpendicular to the plane of the integrated circuit. As shown in FIG. 4A, cooling structure 400 has an inlet 402 to introduce the coolant and an outlet 404 to remove the coolant from cooling structure 400. As shown in FIG. 4B, the coolant passes into cooling structure 400 and comes into contact with center 406 of the integrated circuit (high-power region). The coolant is then transferred from center 406 to four corners 408 of the integrated circuit, i.e., the low-power regions (as depicted by the curved arrows). Thereafter, the coolant is removed from outlet 404 of cooling structure 400.

The apparatus for implementing the disclosed invention is described hereinafter. The apparatus for the disclosed invention comprises an inlet for the coolant, means for transferring the coolant from the high-power region to the low-power region of the integrated circuit, and an outlet for removing the coolant from the integrated circuit.

The inlet for introducing the coolant may be a duct that transports the coolant from the coolant reservoir to the high-power region of the integrated circuit. The inlets are designed, keeping in mind the considering tradeoff between thermal performance and pressure losses in the fluid stream. These inlets can be designed and optimized to direct fluid preferentially to minimize the creation of hot spots. The system inlets/ducting may be composed of a variety of materials including plastics (for easy molding) or metals (for enhanced thermal performance).

Means for transferring the coolant may include a chamber in which the liquid flows from the high-power region to the low-power region of the integrated circuit. The chamber stays in close contact with the integrated circuit so that the heat from the integrated circuit can be transferred to the coolant in the chamber. The chamber can be made of a material that has high thermal conductivity, for example, copper, silver, nickel, graphite or aluminum. Inside the chamber, the fluid may be directed with the assistance of channels or fin structures typically composed of aluminum, copper or similar high thermal conductivity materials. Implementing a closed-loop cooling system would include a pump to propel the fluid, and a heat exchanger where the heat removed from the source is expelled into the environment. An open-loop system would typically include a pump to propel the fluid and a large reservoir of fluid from which cool fluid is drawn and into which the heated fluid is expelled.

The outlet for removing the coolant may be a duct that transports the coolant from the low-power region of the integrated circuit to the coolant reservoir. The design and material used for the construction of outlets is similar to that of the inlets. The system for implementing the invention also comprises a pump for introducing the coolant into the integrated circuit, transferring the coolant from the high-power region to the low-power region of the integrated circuit, and then removing the coolant from the integrated circuit.

In accordance with another embodiment of the disclosed invention, the integrated circuit may comprise multiple high-power and low-power regions. In such a case, there may be multiple inlets that are connected to the high-power regions of the integrated circuit. Similarly, there may be multiple outlets that are connected to the low-power regions of the integrated circuit.

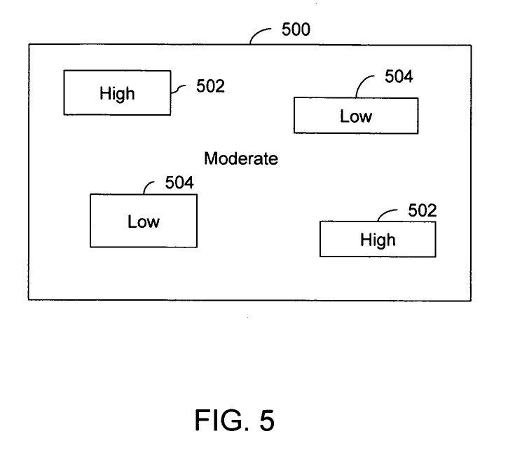

The disclosed invention may also be used to cool an integrated circuit that has high, moderate and low power regions. FIG. 5 shows such an integrated circuit. Integrated circuit 500 comprises high-power regions 502 and low-power regions 504. The remaining portion of the integrated circuit is the moderate power region.

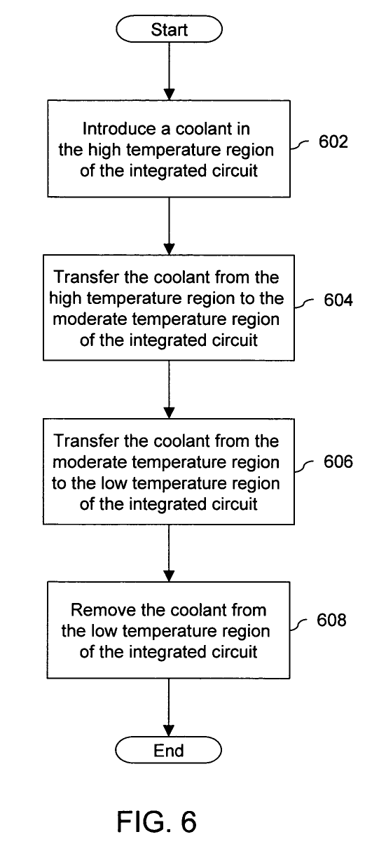

FIG. 6 is a flowchart illustrating the method of cooling an integrated circuit, which has high, moderate and low power regions, in accordance with yet another embodiment of the disclosed invention. The flowchart shows a single cooling cycle that is repeated multiple times in the process of cooling the integrated circuit. At step 602, a coolant is introduced in the high-power region of the integrated circuit. The coolant is then transferred to the moderate power region of the integrated circuit at step 604. At step 606, the coolant is transferred from the moderate power region to the low-power region of the integrated circuit. Thereafter, the coolant is removed from the integrated circuit, as shown at step 608.

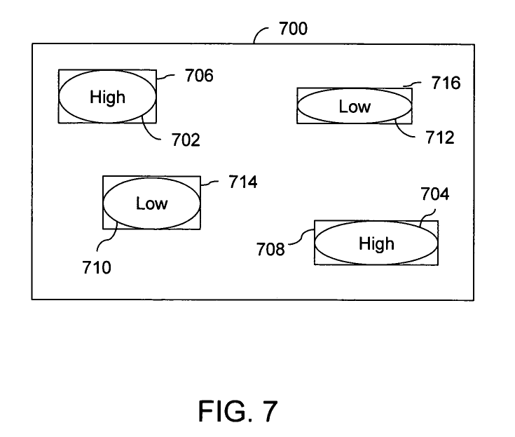

FIG. 7 is a block diagram of an exemplary cooling structure 700 that can be used to cool an integrated circuit, which has high, moderate and low power regions. Integrated circuit 700 has inlets 702 and 704 connected to high-power regions 706 and 708, respectively. As shown in the figure, the coolant is introduced into the inlets perpendicular to the plane of integrated circuit 700. In order to remove the coolant from integrated circuit 700, outlets 710 and 712 are connected to low-power regions 714 and 716 of integrated circuit 700. Inlets 702 and 704 are connected to outlets 710 and 712 through a chamber in which the liquid flows from the high-power regions to the low-power regions of the integrated circuit. The chamber stays in close contact with the integrated circuit so that the heat from the integrated circuit can be transferred to the coolant in the chamber.

Although the disclosed invention has been described with reference to an integrated circuit, it should be apparent to one skilled in the art that the disclosed invention may be used to cool any non-uniformly heated heat source. Examples of such non-uniformly heated sources include optoelectronic devices, power circuitry, mirrors and reflectors used in telescopic and laser applications, and optics in such applications as photolithographic equipment.

While the preferred embodiments of the invention have been illustrated and described, it will be clear that the invention is not limited to these embodiments only. Numerous modifications, changes, variations, substitutions and equivalents will be apparent to those skilled in the art, without departing from the spirit and scope of the invention as described in the claims.

1. An apparatus for cooling a non-uniformly heated integrated circuit, the integrated circuit having at least one low-power region and at least one high-power region, the apparatus comprising:
a. at least one inlet for a coolant, the inlet being connected with a high-power region of the integrated circuit;
b. means for transferring the coolant from the high-power region to a low-power region of the integrated circuit; and
c. at least one outlet for the coolant, the outlet being connected to the low-power region of the integrated circuit.

2. The apparatus as recited in claim 1 wherein the coolant is a single phase coolant.

3. The apparatus as recited in claim 1 wherein the coolant is a two phase coolant.

4. The apparatus as recited in claim 1 wherein the means for transferring the coolant comprises a chamber, the chamber being connected to the inlet and the outlet, the chamber being in close contact with the integrated circuit.

5. The apparatus as recited in claim 4 wherein the chamber is made of high thermal conductivity material.

6. The apparatus as recited in claim 4 wherein the chamber has channels for directing the coolant.

7. The apparatus as recited in claim 1 further comprising a pump for introducing the coolant into the integrated circuit, transferring the coolant from the high-power region to the low-power region of the integrated circuit and removing the coolant from the integrated circuit.

8. A method for cooling a non-uniformly heated integrated circuit, the integrated circuit having at least one low-power region and at least one high-power region, the method comprising the steps of:
a. introducing a coolant in a high-power region of the integrated circuit;
b. transferring the coolant from the high-power region to a low-power region of the integrated circuit; and
c. removing the coolant from the low-power region of the integrated circuit.

9. The method as recited in claim 8 wherein the coolant is introduced parallel to the plane of the integrated circuit.

10. The method as recited in claim 8 wherein the coolant is introduced perpendicular to the plane of the integrated circuit.

11. An apparatus for cooling a non-uniformly heated integrated circuit, the integrated circuit having at least one low-power region, at least one moderate power region and at least one high-power region, the apparatus comprising:
a. at least one inlet for a coolant, the inlet being connected with a high-power region of the integrated circuit;
b. means for transferring the coolant from the high-power region to a moderate power region of the integrated circuit;
c. means for transferring the coolant from the moderate power region to a low-power region of the integrated circuit; and
d. at least one outlet for the coolant, the outlet being connected to the low-power region of the integrated circuit.

12. A method for cooling a non-uniformly heated integrated circuit, the integrated circuit having at least one low-power region, at least one moderate power region and at least one high-power region, the method comprising the steps of:
a. introducing a coolant in a high-power region of the integrated circuit;
b. transferring the coolant from the high-power region to a moderate power region of the integrated circuit;
c. transferring the coolant from the moderate power region to a low-power region of the integrated circuit; and
d. removing the coolant from the low-power region of the integrated circuit.

13. An apparatus for cooling a non-uniformly heated heat source, the heat source having at least one low-power region and at least one high-power region, the apparatus comprising:
a. at least one inlet for a coolant, the inlet being connected with a high-power region of the heat source;
b. means for transferring the coolant from the high-power region to a low-power region of the heat source; and
c. at least one outlet for the coolant, the outlet being connected to the low-power region of the heat source.

14. A method for cooling a non-uniformly heated heat source, the heat source having at least one low-power region and at least one high-power region, the method comprising the steps of:
a. introducing a coolant in a high-power region of the heat source;
b. transferring the coolant from the high-power region to a low-power region of the heat source; and
c. removing the coolant from the low-power region of the heat source.
